(19) United States
(12) Patent Application Publication
(10) Pub. No.: US 2025/0343209 A1
(43) Pub. Date: Nov. 6, 2025

(54) DISPLAY PANEL

(71) Applicant: AUO Corporation, Hsinchu City (TW)

(72) Inventors: Chih-Kai WANG, Hsinchu City (TW); Yea-Ching CHEN, Hsinchu City (TW)

(21) Appl. No.: 18/957,932

(22) Filed: Nov. 25, 2024

(30) Foreign Application Priority Data
May 1, 2024 (TW) 113116291

(51) Int. Cl. H01L 25/075; H01L 33/54

(52) U.S. Cl. CPC H01L 25/0753; H10H 20/853

(57) ABSTRACT

A display panel includes a substrate and a plurality of light-emitting diode (LED) pixels. The LED pixels are located on the substrate, in which each of the LED pixels includes a first subpixel, a second subpixel, and a third subpixel. The first subpixels of the LED pixels are arranged along a first direction. Each of the LED pixels has the first subpixel, the second subpixel, and the third subpixel in order along a second direction. The first direction is different from the second direction. The first subpixels, the second subpixels, and the third subpixels of adjacent two of the LED pixels along at least one of the first direction and the second direction have different polarity directions.

### RELATED APPLICATIONS

This application claims priority to Taiwan Application Serial Number 113116291, filed May 1, 2024, which is herein incorporated by reference.

### BACKGROUND

### Field of Invention The present disclosure relates to a display panel.

### Description of Related Art

Under the circumstance of large screen curved displays, curved screens that allow for multiple viewing angles or screens that are placed at an angle are prone to color shift. This phenomenon is mainly due to three factors, the difference in viewing angles between red light and blue and green lights, the asymmetry of the light field of the light-emitting diode (LED) pixel chip itself, and the pixels with large viewing angles block lights of one another. Therefore, there is a need to provide a display panel that is able to resolve the above three problems.

### SUMMARY

One technical aspect of the present disclosure is to provide a display panel.

A display panel includes a substrate and a plurality of light-emitting diode (LED) pixels. The LED pixels are located on the substrate. Each of the LED pixels has a first subpixel, a second subpixel, and a third subpixel. The first subpixels of the LED pixels are arranged along a first direction. Each of the LED pixels has the first subpixel, the second subpixel, and the third subpixel in order along a second direction. The second direction is different from the first direction. The first subpixels, the second subpixels, and the third subpixels of adjacent two of the LED pixels along at least one of the first direction and the second direction have different polarity directions.

In the foregoing, the first subpixels of the LED pixels are arranged along the second direction at equal distances.

In the foregoing, a negative terminal of the third subpixel of one of the LED pixels is close to a negative terminal of the third subpixel of another LED pixel adjacent to it along the first direction, and a negative terminal of the third subpixel of one of the LED pixels is close to a negative terminal of the first subpixel of another LED pixel adjacent to it along the second direction.

In the foregoing, a negative terminal of the third subpixel of one of the LED pixels is close to a negative terminal of the third subpixel of another LED pixel adjacent to it along the first direction, and a negative terminal of the third subpixel of one of the LED pixels is close to a positive terminal of the first subpixel of another LED pixel adjacent to it along the second direction.

In the foregoing, a negative terminal of the third subpixel of one of the LED pixels is close to a positive terminal of the third subpixel of another LED pixel adjacent to it along the first direction, and a negative terminal of the third subpixel of one of the LED pixels is close to a positive terminal of the first subpixel of another LED pixel adjacent to it along the second direction.

In the foregoing, a negative terminal of at least one subpixel of one of the LED pixels is adjacent to a positive terminal of another subpixel.

In the foregoing, the display panel further includes an optical retaining layer. The optical retaining layer surrounds the first subpixels, the second subpixels, and the third subpixels.

In the foregoing, the optical retaining layer includes side blackening, single chip encapsulation black cup walls, or single chip encapsulation white cup walls.

In the foregoing, each of the first subpixels, the second subpixels, and the third subpixels includes a thin film LED.

In the foregoing, the substrate has a plurality of recesses, and the first subpixels, the second subpixels, and the third subpixels are respectively located in the recesses.

In the foregoing, the display panel further includes an encapsulation substrate layer. The encapsulation substrate layer is located between the substrate and the LED pixels. The encapsulation substrate layer has a plurality of blocks and each of the LED pixels is located on one of the blocks of the encapsulation substrate layer.

In the foregoing, the display panel further includes an encapsulation substrate layer. The encapsulation substrate layer is located between the substrate and the LED pixels. The encapsulation substrate layer has a plurality of blocks, and each four adjacent LED pixels are located on one of the blocks of the encapsulation substrate layer.

In the above embodiments of the present disclosure, since the projections of first subpixels of the LED pixels substantially overlap in the second direction, and each of the LED pixels has the first subpixel, the second subpixel, and the third subpixel in order along the second direction, the first subpixels, the second subpixels, and the third subpixels of the LEDs can achieve light field symmetry through adjusting the polarity directions of the chip. As a result, the influence of color shift can be improved to enhance the viewing experience at a wide angle.

It is to be understood that both the foregoing general description and the following detailed description are by examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts a top view of a display panel according to one embodiment of the present disclosure;

FIG. 2 depicts a top view of a display panel according to another embodiment of the present disclosure;

FIG. 3 depicts a top view of a display panel according to still another embodiment of the present disclosure;

FIG. 4 depicts a top view of a display panel according to yet another embodiment of the present disclosure;

FIG. 5 depicts a cross-sectional view of a display panel according to another embodiment of the present disclosure;

FIG. 6 depicts a cross-sectional view of a display panel according to still another embodiment of the present disclosure;

FIG. 7 depicts a cross-sectional view of a display panel according to yet another embodiment of the present disclosure;

FIG. 8 depicts a cross-sectional view of a display panel according to another embodiment of the present disclosure;

FIG. 9 depicts a cross-sectional view of a display panel according to still another embodiment of the present disclosure;

FIG. 10 depicts a cross-sectional view of a display panel according to yet another embodiment of the present disclosure;

FIG. 11 depicts a top view of the display panel in FIG. 10;

FIG. 12 depicts a cross-sectional view of a display panel according to another embodiment of the present disclosure; and

FIG. 13 depicts a top view of the display panel in FIG. 12.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one component or feature's relationship to another component(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

As used herein, “about,” “approximately,” or “substantially” includes the stated value and average values within acceptable deviations of the particular value determined by one of ordinary skill in the art, in consideration of the measurements discussed and the specific amounts of errors associated with the measurements (that is, limitation of the measurement system). For example, “about” can mean within one or more standard deviations of the stated value, or within ±30%, ±20%, ±10%, ±5% of the stated value. Additionally, the term “about,” “approximately,” or “substantially” used herein may select a more acceptable deviation range or standard deviation depending on the optical properties, etching properties, or other properties, and may not be applied to all properties with one standard deviation.

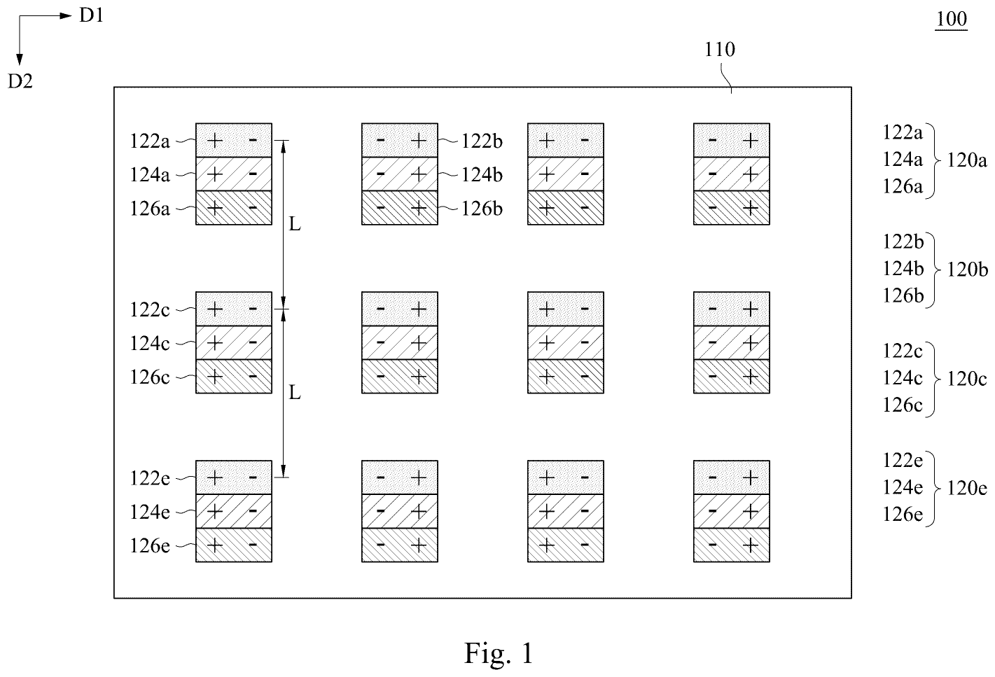

FIG. 1 depicts a top view of a display panel 100 according to one embodiment of the present disclosure. A description is provided with reference to FIG. 1. The display panel 100 includes a substrate 110 and a plurality of LED pixels 120a, 120b, 120c, 120e. The LED pixels 120a, 120b, 120c, 120e are located on the substrate 110. The LED pixels 120a, 120b, 120c, 120e respectively include first subpixels 122a, 122b, 122c, 122e, second subpixels 124a, 124b, 124c, 124e, and third subpixels 126a, 126b, 126c, 126e. Take the

LED pixels 120a, 120b for example, the first subpixels 122a, 122b of the LED pixels 120a, 120b are arranged along a first direction D1. A line connecting centers of the first subpixels 122a, 122b, 122c, 122e of the LED pixels 120a, 120b, 120c, 120e is substantially a straight line, that is, projections of the first subpixels 122a, 122b, 122c, 122e substantially overlap in a second direction D2. In addition, take the LED pixel 120a for example, the LED pixel 120a has the first subpixel 122a, the second subpixel 124a, and the third subpixel 126a in order along the second direction D2. The second direction D2 is different from the first direction D1.

Additionally, a distance L between the first subpixel (such as the subpixel 122a) of one of the LED pixels (such as the LED pixel 120a) and the first subpixel (such as the subpixel 122c) of another LED pixel adjacent to it along the second direction D2 (such as the LED pixel 120c) is substantially the same on the substrate 110. That is to say, the distance L between the first subpixel 122a of the LED pixel 120a and the first subpixel 122c of the LED pixel 120c is equal to the distance L between the first subpixel 122c of the LED pixel 120c and the first subpixel 122e of the LED pixel 120e. In addition to that, in the present embodiment, take the LED pixel 120a and the LED pixel 120b for example. A negative terminal (−) of the third subpixel 126a of the LED pixel 120a is close to a negative terminal (−) of the third subpixel 126b of the LED pixel 120b adjacent to it along the first direction D1. Take the LED pixel 120a and the LED pixel 120c for example. The negative terminal (−) of the third subpixel 126a of the LED pixel 120a is close to a negative terminal (−) of the first subpixel 122c of the LED pixel 120c adjacent to it along the second direction D2. In other words, the first subpixels 122a, 122b, the second subpixels 124a, 124b, and the third subpixels 126a, 126b of the adjacent LED pixels 120a, 120b along the first direction D1 have different polarity directions. In the present embodiment, the polarity directions of three subpixels of the LED pixel 120a are all opposite to the polarity directions of three subpixels of the LED pixel 120b.

Since the projections of the first subpixels 122a, 122b of the LED pixels 120a, 120b substantially overlap in the second direction D2, and the LED pixel 120a has the first subpixel 122a, the second subpixel 124a, and the third subpixel 126a in order along the second direction D2, the first subpixels, the second subpixels, and the third subpixels of the LEDs can achieve light field symmetry through adjusting the polarity directions of the chip. As a result, the influence of color shift can be improved to enhance the viewing experience at a wide angle.

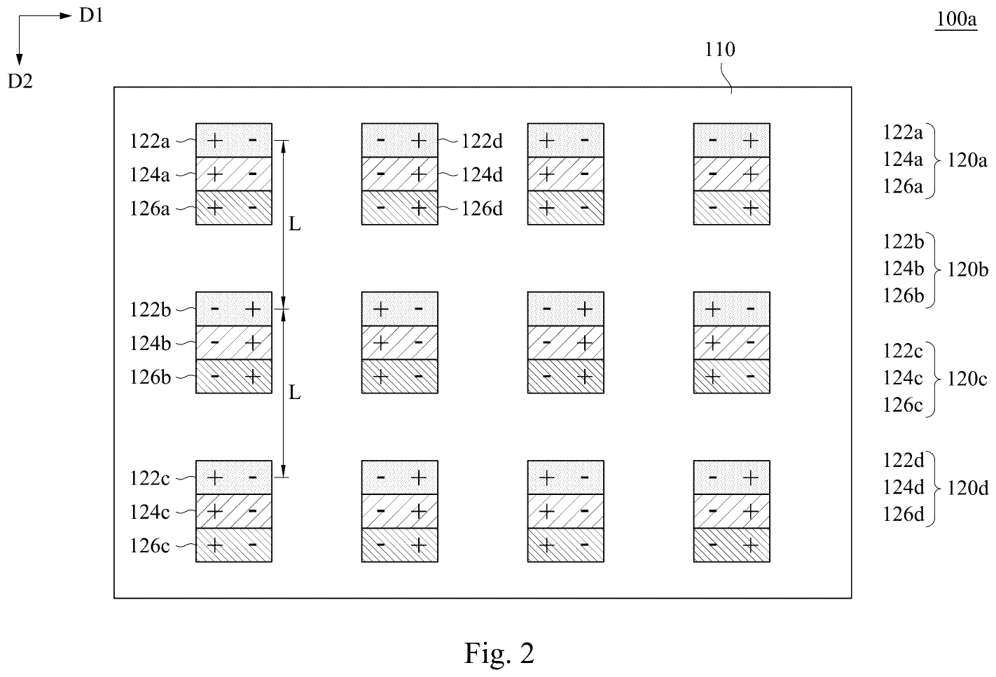

FIG. 2 depicts a top view of a display panel 100a according to another embodiment of the present disclosure. A description is provided with reference to FIG. 2. The display panel 100a includes the substrate 110 and the plurality of LED pixels 120a, 120b, 120c and LED pixels 120d. The LED pixels 120a, 120b, 120c, 120d are located on the substrate 110. The LED pixels 120a, 120b, 120c, 120d respectively include the first subpixels 122a, 122b, 122c and a first subpixel 122d, the second subpixels 124a, 124b, 124c and a second subpixel 124d, and the third subpixels 126a, 126b, 126c and a third subpixel 126d. A difference between the present embodiment and the embodiment of FIG. 1 lies in that, take the LED pixel 120a and the LED pixel 120d for example, the negative terminal (−) of the third subpixel 126a of the LED pixel 120a is close to a negative terminal (−) of the third subpixel 126d of the LED pixel 120d adjacent to it along the first direction D1 in the present embodiment. Take the LED pixel 120a and the LED pixel 120b for example, the negative terminal (−) of the third subpixel 126a of the LED pixel 120a is close to a positive terminal (+) of the first subpixel 122b of the LED pixel 120b adjacent to it along the second direction D2. In other words, the first subpixels 122a, 122d, the second subpixels 124a, 124d, and the third subpixels 126a, 126d of the adjacent LED pixels 120a, 120d along the first direction D1 have different polarity directions. The first subpixels 122a, 122b, the second subpixels 124a, 124b, and the third subpixels 126a, 126b of the adjacent LED pixels 120a, 120b along the second direction D2 have different polarity directions. In the present embodiment, the polarity directions of the three subpixels of the LED pixel 120a are all opposite to the polarity directions of the three subpixels of the LED pixel 120b, and the polarity directions of the three subpixels of the LED pixel 120a are all opposite to the polarity directions of three subpixels of the LED pixel 120d.

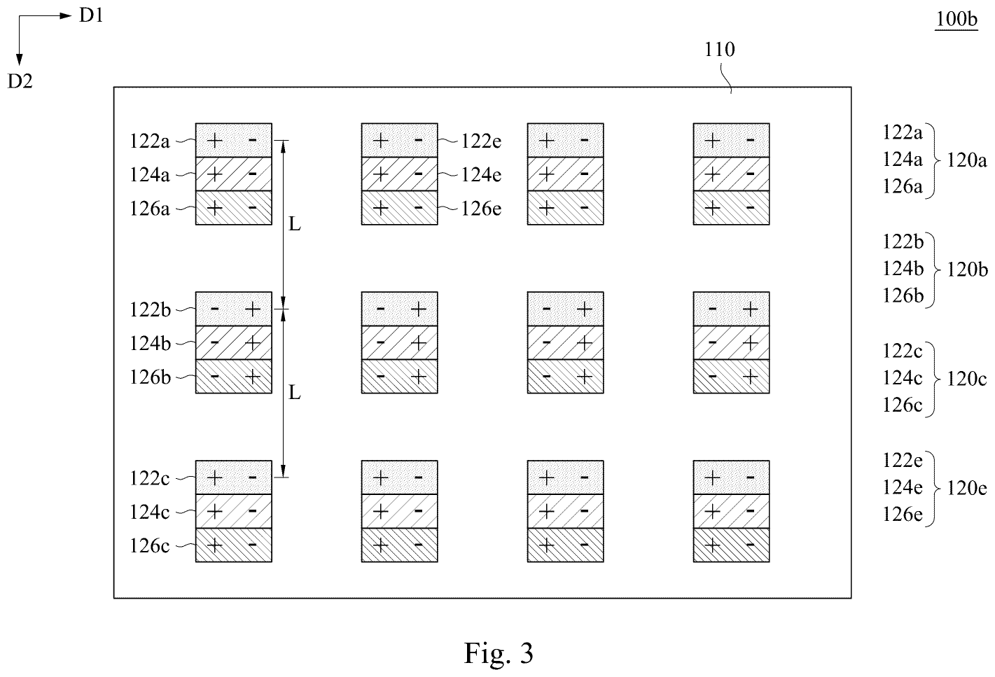

FIG. 3 depicts a top view of a display panel 100b according to still another embodiment of the present disclosure. A description is provided with reference to FIG. 3. The display panel 100b includes the substrate 110 and the plurality of LED pixels 120a, 120b, 120c, 120e. The LED pixels 120a, 120b, 120c, 120e are located on the substrate 110. The LED pixels 120a, 120b, 120c, 120e respectively include the first subpixels 122a, 122b, 122c, 122e, the second subpixels 124a, 124b, 124c, 124e, and the third subpixels 126a, 126b, 126c, 126e. A difference between the present embodiment and the embodiment of FIG. 1 lies in that, take the LED pixel 120a and the LED pixel 120e for example, the negative terminal (-) of the third subpixel 126a of the LED pixel 120a is close to a positive terminal (+) of the third subpixel 126e of the LED pixel 120e adjacent to it along the first direction D1 in the present embodiment. Take the LED pixel 120a and the LED pixel 120b for example, the negative terminal (−) of the third subpixel 126a of the LED pixel 120a is close to the positive terminal (+) of the first subpixel 122b of the LED pixel 120b adjacent to it along the first direction D2. In other words, the first subpixels 122a, 122b, the second subpixels 124a, 124b, and the third subpixels 126a, 126b of the adjacent LED pixels 120a, 120b along the second direction D2 have different polarity directions. In the present embodiment, the polarity directions of the three subpixels of the LED pixel 120a are all opposite to the polarity directions of the three subpixels of the LED pixel 120b.

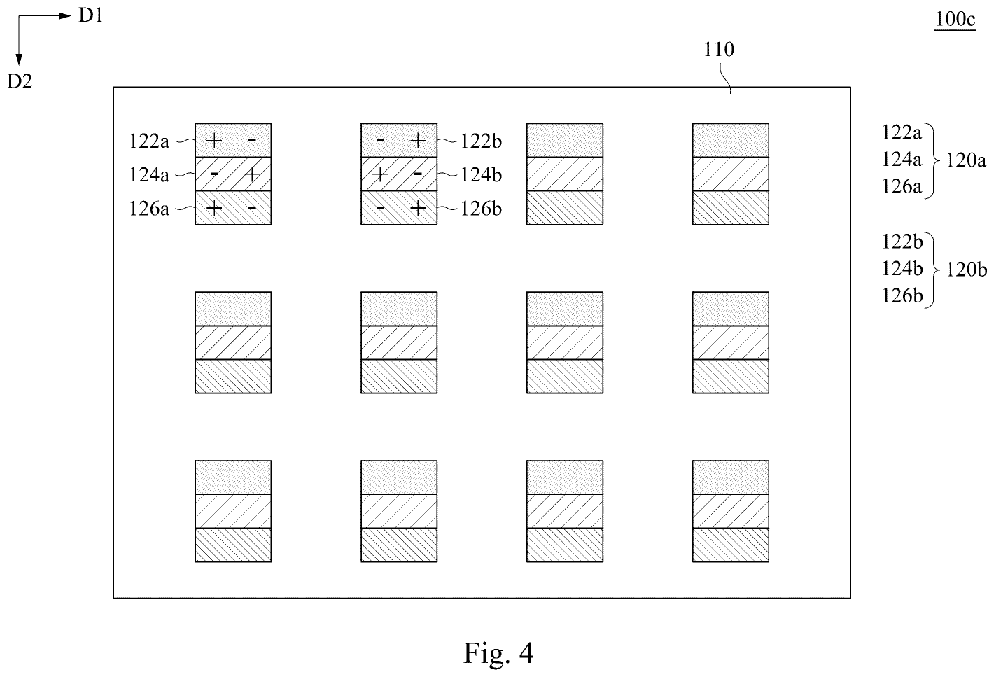

FIG. 4 depicts a top view of a display panel 100c according to yet another embodiment of the present disclosure. A description is provided with reference to FIG. 4. The display panel 100c includes the substrate 110 and the plurality of LED pixels 120a, 120b. The LED pixels 120a, 120b are located on the substrate 110. The LED pixels 120a, 120b respectively include the first subpixels 122a, 122b, the second subpixels 124a, 124b, and the third subpixels 126a, 126b. A difference between the present embodiment and the embodiment of FIG. 1 lies in that, take the LED pixel 120a for example, the negative terminal (−) of the third subpixel 126a of the LED pixel 120a is adjacent to a positive terminal (+) of the second subpixel 124a of the LED pixel 120a in the present embodiment. In other words, the negative terminal (−) of the third subpixel 126a of the LED pixel 120a and the positive terminal (+) of the second subpixel 124a of the LED pixel 120a are arranged along the second direction D2. That is, a negative terminal of one of three subpixels of one of LED pixels is adjacent to a positive terminal of an adjacent subpixel of the one of LED pixels.

It is thus understood from the embodiments of FIG. 1 to FIG. 4 that the first subpixels, the second subpixels, and the third subpixels of adjacent two of the LED pixels 120a, 120b, 120c, 120d, 120e along at least one of the first direction D1 and the second direction D2 have different polarity directions.

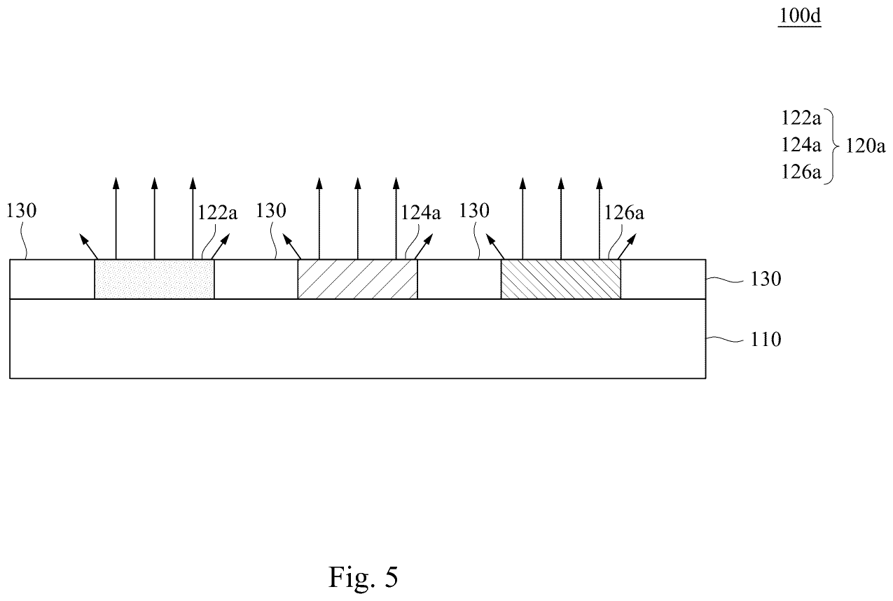

FIG. 5 depicts a cross-sectional view of a display panel 100d according to another embodiment of the present disclosure. A description is provided with reference to FIG. 5. The display panel 100d includes the substrate 110 and the LED pixel 120a. The LED pixel 120a is located on the substrate 110. The LED pixel 120a includes the first subpixel 122a, the second subpixel 124a, and the third subpixel 126a. A difference between the present embodiment and the embodiment of FIG. 1 lies in that the display panel 100d further includes an optical retaining layer 130 in the present embodiment. The optical retaining layer 130 surrounds the first subpixel 122a, the second subpixel 124a, and the third subpixel 126a. In addition, in the present embodiment the optical retaining layer 130 includes side blackening, and the side blackening covers the entire substrate 110. Additionally, a material of the side blackening may be, for example, a silicone-based material, an epoxy resin-based material, or an acrylic-based material. The optical retaining layer 130 is configured to block side lights of the first subpixel 122a, the second subpixel 124a, and the third subpixel 126a, so that a different side light pattern of the first subpixel 122a (that is, a red subpixel) is not affected by side light patterns of the second subpixel 124A and the third subpixel 126A.

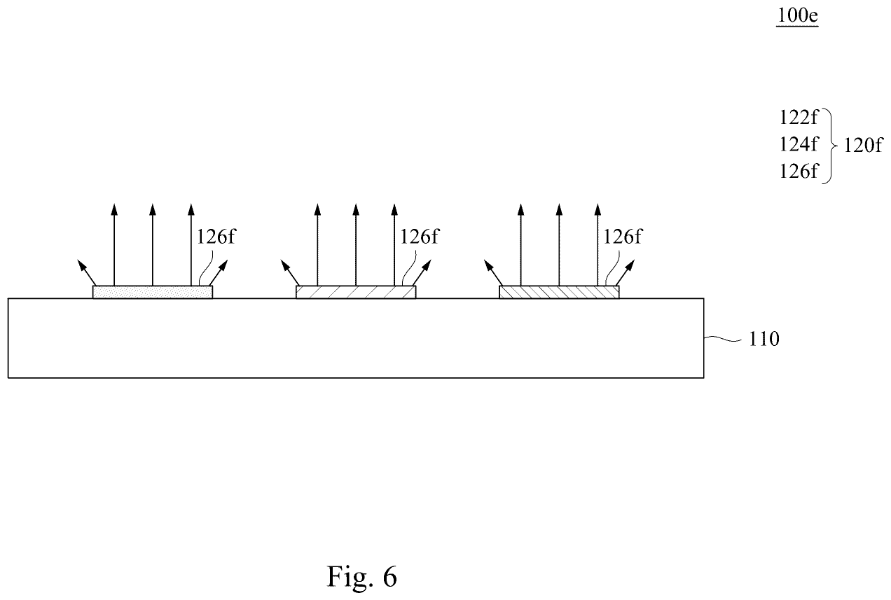

FIG. 6 depicts a cross-sectional view of a display panel 100e according to still another embodiment of the present disclosure. A description is provided with reference to FIG. 6. The display panel 100e includes the substrate 110 and an LED pixel 120f. The LED pixel 120f is located on the substrate 110. The LED pixel 120f includes a first subpixel 122f, a second subpixel 124f, and a third subpixel 126f. A difference between the present embodiment and the embodiment of FIG. 5 lies in that each of the first subpixel 122f, the second subpixel 124f, and the third subpixel 126f includes a thin film LED in the present embodiment. The smaller height of the thin film LEDs can minimize the differences between the side light patterns of LEDs of different colors. As a result, differences between red light pattern and green and blue light patterns can also be avoided.

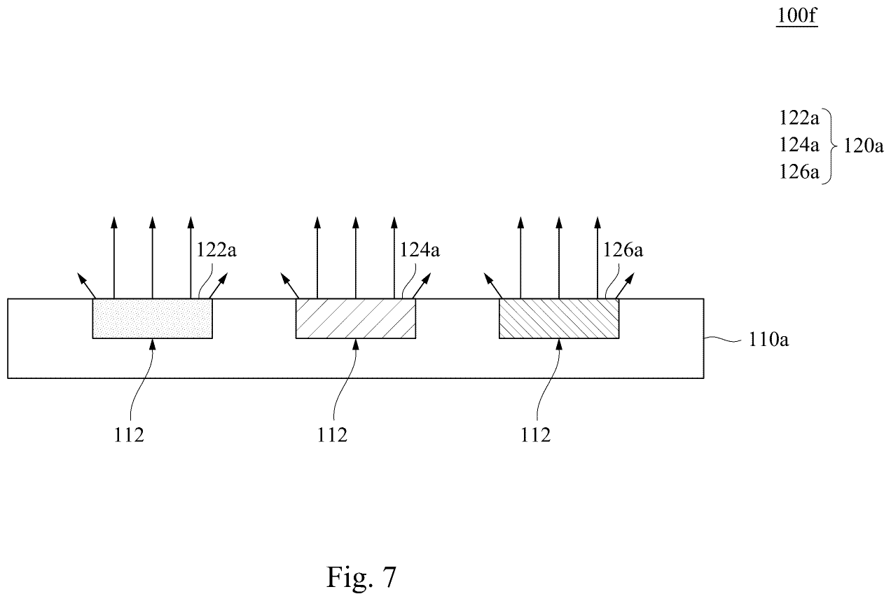

FIG. 7 depicts a cross-sectional view of a display panel 100f according to yet another embodiment of the present disclosure. A description is provided with reference to FIG. 7. The display panel 100f includes a substrate 110a and the LED pixel 120a. The LED pixel 120a is located on the substrate 110a. The LED pixel 120a includes the first subpixel 122a, the second subpixel 124a, and the third subpixel 126a. A difference between the present embodiment and the embodiment of FIG. 5 lies in that the substrate 110a has a plurality of recesses 112 in the present embodiment, and the first subpixel 122a, the second subpixel 124a, and the third subpixel 126a are respectively located in the recesses 112. The recesses 112 of the substrate 110a can be configured to block side lights of the first subpixel 122a, the second subpixel 124a, and the third subpixel 126a, so that differences between side light performance of the first subpixel 122a, the second subpixel 124a, and the third subpixel 126a are not too significant.

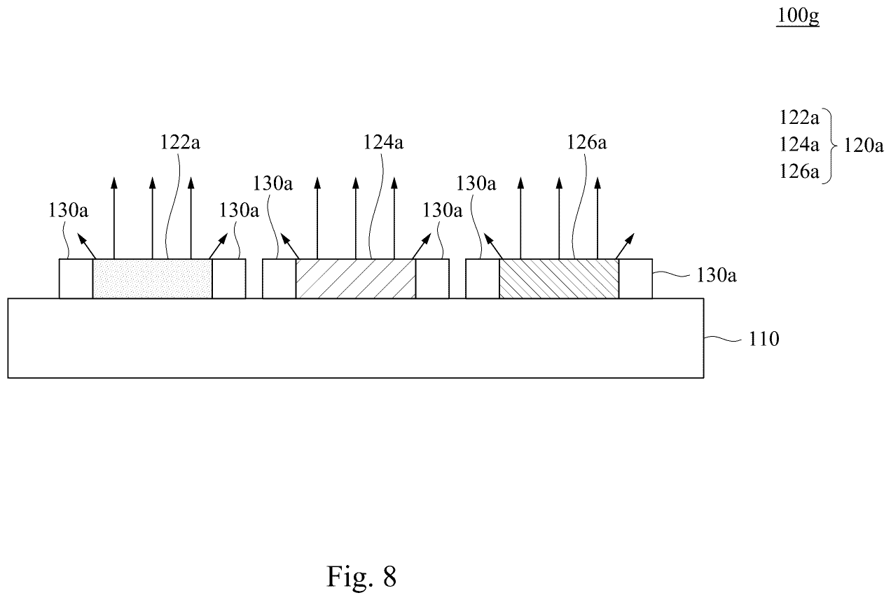

FIG. 8 depicts a cross-sectional view of a display panel 100g according to another embodiment of the present disclosure. A description is provided with reference to FIG. 8. The display panel 100g includes the substrate 110 and the LED pixel 120a. The LED pixel 120a is located on the substrate 110. The LED pixel 120a includes the first subpixel 122a, the second subpixel 124a, and the third subpixel 126a. A difference between the present embodiment and the embodiment of FIG. 5 lies in that the display panel 100g further includes an optical retaining layer 130a in the present embodiment. The optical retaining layer 130a surrounds the first subpixel 122a, the second subpixel 124a, and the third subpixel 126a. In addition, in the present embodiment, the optical retaining layer 130 includes single chip encapsulation black cup walls, and the single chip encapsulation black cup walls surround the first subpixel 122a, the second subpixel 124a, and the third subpixel 126a separately. Additionally, a material of the single chip encapsulation black cup wall may include a silicone-based material, an epoxy resin-based material, or an acrylic-based material. The optical retaining layer 130 is configured to block side lights of the first subpixel 122a, the second subpixel 124a, and the third subpixel 126a.

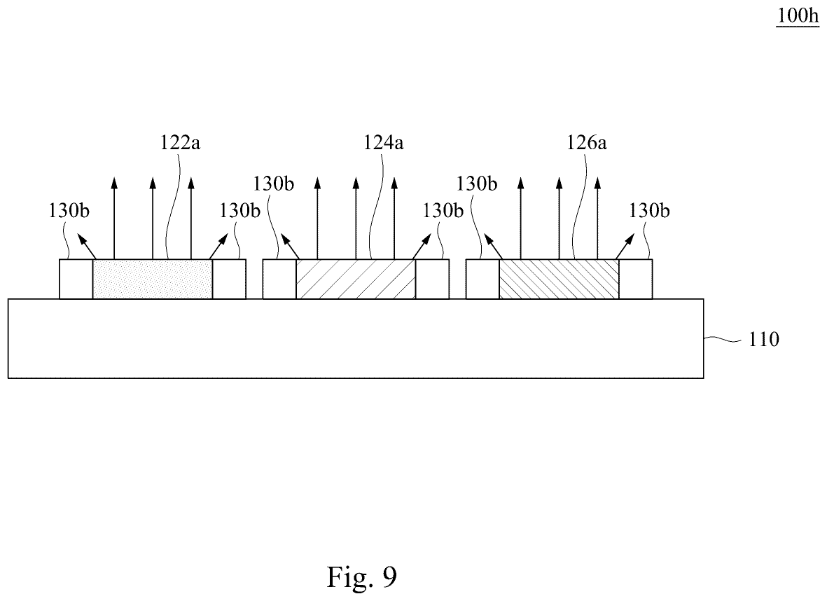

FIG. 9 depicts a cross-sectional view of a display panel 100h according to still another embodiment of the present disclosure. A description is provided with reference to FIG. 9. The display panel 100h includes the substrate 110 and the LED pixel 120a. The LED pixel 120a is located on the substrate 110. The LED pixel 120a includes the first subpixel 122a, the second subpixel 124a, and the third subpixel 126a. A difference between the present embodiment and the embodiment of FIG. 8 lies in that an optical retaining layer 130b of the display panel 100h includes single chip encapsulation white cup walls in the present embodiment. The single chip encapsulation white cup walls surround the first subpixel 122a, the second subpixel 124a, and the third subpixel 126a separately. In addition to that, a material of the single chip encapsulation white cup wall may include a silicone-based material, an epoxy resin-based material, or an acrylic-based material.

The above embodiments of FIG. 5 to FIG. 9 can all change the original five-sided emitting first subpixel 122a, second subpixel 124a, and third subpixel 126a into a state close to a single-sided emitting state. Therefore, under the circumstance that the light patterns of the side lights of the three subpixels are different, the problem of different light patterns of the side lights can be resolved, thus resolving the influence of color shift and enhancing the viewing experience at a wide angle.

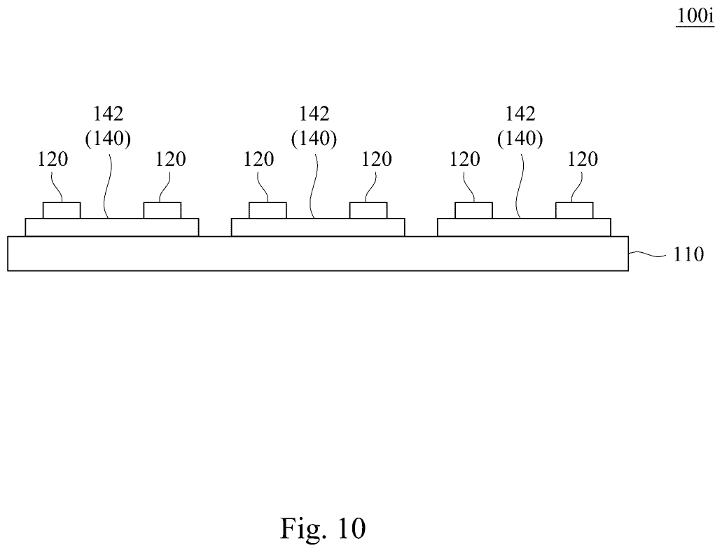

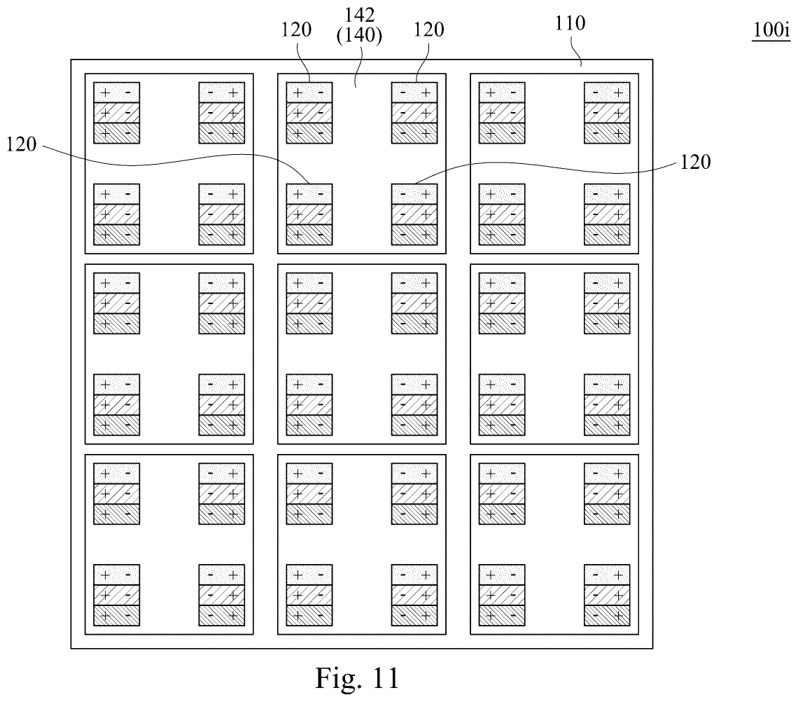

FIG. 10 depicts a cross-sectional view of a display panel 100i according to yet another embodiment of the present disclosure. FIG. 11 depicts a top view of the display panel 100i in FIG. 10. A description is provided with reference to FIG. 10 and FIG. 11. The display panel 110i includes the substrate 110 and a plurality of LED pixels 120. A difference between the present embodiment and the embodiment of FIG. 1 lies in that the display panel 100i further includes an encapsulation substrate layer 140 in the present embodiment. The encapsulation substrate layer 140 is located between the substrate 110 and the LED pixels 120. The encapsulation substrate layer 140 has a plurality of blocks 142. In addition, each four adjacent LED pixels 120 are located on one of the blocks 142 of the encapsulation substrate layer 140.

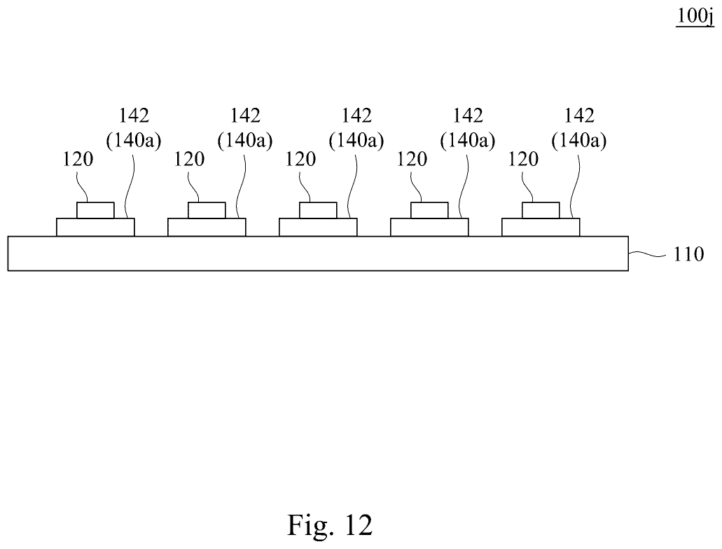

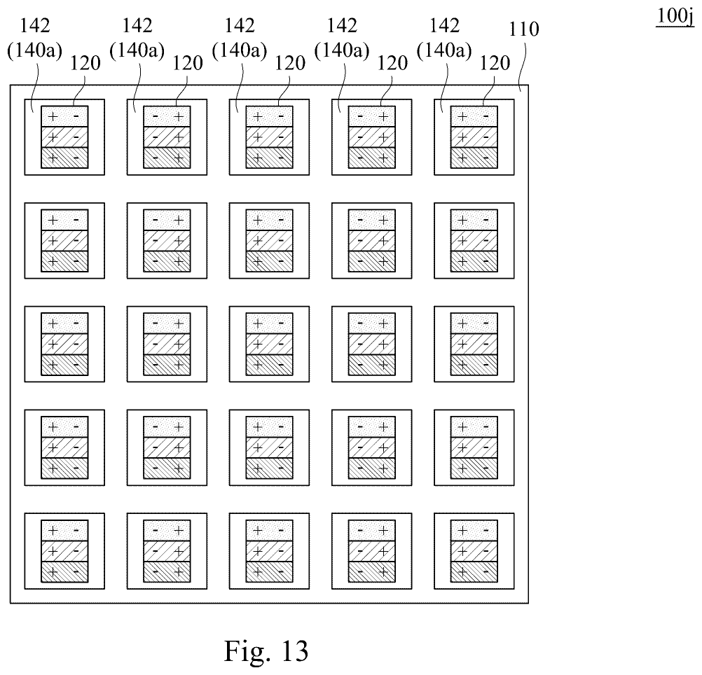

FIG. 12 depicts a cross-sectional view of a display panel 100j according to another embodiment of the present disclosure. FIG. 13 depicts a top view of the display panel 100j in FIG. 12. A description is provided with reference to FIG. 12 and FIG. 13. The display panel 100j includes the substrate 110 and the plurality of LED pixels 120. A difference between the present embodiment and the embodiment of FIG. 1 lies in that the display panel 100j further includes an encapsulation substrate layer 140a in the present embodiment. The encapsulation substrate layer 140a is located between the substrate 110 and the LED pixels 120. The encapsulation substrate layer 140a has the plurality of blocks 142, and each of the LED pixels 120 is located on one of the blocks 142 of the encapsulation substrate layer 140.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure covers modifications and variations of this disclosure provided they fall within the scope of the following claims and their equivalents.

What is claimed is:

1. A display panel, comprising:
a substrate; and
a plurality of light-emitting diode (LED) pixels located on the substrate, wherein each of the LED pixels has a first subpixel, a second subpixel, and a third subpixel, the first subpixels of the LED pixels are arranged along a first direction, each of the LED pixels has the first subpixel, the second subpixel, and the third subpixel in order along a second direction, the second direction is different from the first direction, the first subpixels, the second subpixels, and the third subpixels of adjacent two of the LED pixels along at least one of the first direction and the second direction have different polarity directions.

2. The display panel of claim 1, wherein the first subpixels of the LED pixels are arranged along the second direction at equal distances.

3. The display panel of claim 1, wherein a negative terminal of the third subpixel of one of the LED pixels is close to a negative terminal of the third subpixel of another LED pixel adjacent to it along the first direction, and a negative terminal of the third subpixel of one of the LED pixels is close to a negative terminal of the first subpixel of another LED pixel adjacent to it along the second direction.

4. The display panel of claim 1, wherein a negative terminal of the third subpixel of one of the LED pixels is close to a negative terminal of the third subpixel of another LED pixel adjacent to it along the first direction, and a negative terminal of the third subpixel of one of the LED pixels is close to a positive terminal of the first subpixel of another LED pixel adjacent to it along the second direction.

5. The display panel of claim 1, wherein a negative terminal of the third subpixel of one of the LED pixels is close to a positive terminal of the third subpixel of another LED pixel adjacent to it along the first direction, and a negative terminal of the third subpixel of one of the LED pixels is close to a positive terminal of the first subpixel of another LED pixel adjacent to it along the second direction.

6. The display panel of claim 1, wherein a negative terminal of at least one subpixel of one of the LED pixels is adjacent to a positive terminal of another subpixel.

7. The display panel of claim 1, further comprising:
an optical retaining layer surrounding the first subpixels, the second subpixels, and the third subpixels.

8. The display panel of claim 7, wherein the optical retaining layer comprises side blackening, single chip encapsulation black cup walls, or single chip encapsulation white cup walls.

9. The display panel of claim 1, wherein each of the first subpixels, the second subpixels, and the third subpixels comprises a thin film LED.

10. The display panel of claim 1, wherein the substrate has a plurality of recesses, and the first subpixels, the second subpixels, and the third subpixels are respectively located in the recesses.

11. The display panel of claim 1, further comprising:
an encapsulation substrate layer located between the substrate and the LED pixels, wherein the encapsulation substrate layer has a plurality of blocks and each of the LED pixels is located on one of the blocks of the encapsulation substrate layer.

12. The display panel of claim 1, further comprising:
an encapsulation substrate layer located between the substrate and the LED pixels, wherein the encapsulation substrate layer has a plurality of blocks, and each four adjacent LED pixels are located on one of the blocks of the encapsulation substrate layer.

13. A display panel, comprising:
a substrate; and
a plurality of light-emitting diode (LED) pixels located on the substrate, wherein each of the LED pixels has a red subpixel, a green subpixel, and a blue subpixel, the red subpixels of the LED pixels are arranged along a first direction, each of the LED pixels has the red subpixel, the green subpixel, and the blue subpixel in order along a second direction, the red subpixels, the green subpixels, and the blue subpixels of adjacent two of the LED pixels along at least one of the first direction and the second direction have different polarity directions.

14. The display panel of claim 13, wherein the red subpixels of the LED pixels are arranged along the second direction at equal distances.

15. The display panel of claim 13, wherein a negative terminal of the blue subpixel of one of the LED pixels is close to a negative terminal of the blue subpixel of another LED pixel adjacent to it along the first direction, and a negative terminal of the blue subpixel of one of the LED pixels is close to a negative terminal of the red subpixel of another LED pixel adjacent to it along the second direction.
